(19) United States
(12) Patent Application Publication
(10) Pub. No.: US 2024/0103384 A1
(43) Pub. Date: Mar. 28, 2024

(54) METHOD FOR ANALYZING DEFECTS OF A STRUCTURED COMPONENT

(71) Applicant: Carl Zeiss SMT GmbH, Oberkochen (DE)

(72) Inventors: Jan Tusch, Oberkochen (DE); Kay Dornbusch, Oberkochen (DE); Thomas Zeuner, Jena (DE)

(21) Appl. No.: 18/373,359

(22) Filed: Sep. 27, 2023

(30) Foreign Application Priority Data
Sep. 27, 2022 (DE) 102022210225.8

(51) Int. Cl. G03F 7/00; G03F 1/84

(52) U.S. Cl. CPC G03F 7/7065; G03F 1/84; G03F 7/70625

(57) ABSTRACT

An analysis of the defects of a structured component includes a check of a local deviation between an actual structure dimension of the component and a target structure dimension of the component. In this context, the local deviation is checked at a location of a test path along a deviation coordinate which extends across the test path. The test is repeated at a plurality of different test path locations within a test region of the test path. A summed local deviation between the actual structure dimension and the target structure dimension over the test region is determined. The local deviation is compared with a local deviation tolerance value. The summed local deviation is compared with a summation deviation tolerance value. This results in a defect analysis with enhanced significance, which is implementable using a metrology system in particular.

### CROSS-REFERENCE TO RELATED APPLICATION

The present patent application claims the priority of German patent application DE 10 2022 210 225.8, filed on Sep. 27, 2022, the entire content of which is incorporated herein by reference.

### TECHNICAL FIELD

The invention relates to a method for analyzing defects of a structured component. The invention also relates to a computer program product and a metrology system for carrying out such a defect analysis.

### BACKGROUND

A metrology system as known from US 2017/0131 528 A1 (parallel document WO 2016/012 425 A2), from WO 2016/012 426 A1, from US 2017/0132782 A1 and from DE 10 2009 016 858 B4 is used to analyze defects of a structured component in the form of a reticle or a lithography mask in particular. US 2022/0229374 A1 discloses a method for determining a characteristic of a structure-forming process.

### SUMMARY

It is an aspect of the present invention to enhance the significance of a defect analysis, which is implementable using a metrology system in particular.

According to the invention, this aspect is achieved by a method having the features specified in claim 1. The structured component can be a lithography mask or a reticle.

An enhanced significance of the defect analysis arises from the fact that both a local deviation and a summed local deviation are compared with corresponding tolerance values. Small local deviations which are within the local deviation tolerance on an individual basis but when summed within the test region have an intolerable size can be qualified as non-tolerable defects because the summed local deviation is outside the summation deviation tolerance value.

The local deviation tolerance value and the summation deviation tolerance value can each be specified on the basis of calculation models or on the basis of empirical values. The test region can be specified by way of a region of interest (ROI), in particular the dimension of an object field of the metrology system.

The test path can be scanned within the test region in particular.

When determining the summed deviation, the summation carried out can be implemented as an integration and realized with the aid of an appropriate software algorithm.

The deviation coordinate along which the local deviation between the actual structure dimension and the target structure dimension of the component is checked is one and the same deviation coordinate along the entire test path. A deviation measurement direction is therefore the same at all test path locations.

A test path according to claim 2 enables a defect analysis of a rectilinear structure of the component or a rectilinear gap between two structural elements of the component. Horizontal and/or vertical structures of the component in particular can then be subjected to the defect analysis.

A test path according to claim 3 allows correspondingly curved structures of the component in particular to be analyzed. The test path may have an angle of curvature of 90°. This allows a corner structure of the structured component to be analyzed.

A test path according to claim 4 allows correspondingly closed structures on the structured component to be analyzed. The test path can be circular or elliptical. Contact holes in particular can be analyzed using a closed test path.

Extension ratios according to claim 5 have proven to be particularly suitable for a precise examination of the local deviation.

A separate summation according to claim 6 avoids an undesired compensation of positive deviations and negative deviations in the determination of the summed deviation.

A determination of at least one of the measured variables of “maximum intensity,” “minimum intensity” and/or “mean intensity” according to claim 7 enables a measured variable determination for defect analysis that is independent of the test path location-dependent deviation determination. The measured variable determination according to claim 7 can be implemented in parallel or sequentially to the deviation check at the test path locations of the test path.

The measured variable determination enables a defect analysis, in particular by comparing the determined intensities with specified intensity values. Then, the presence of a defect can be inferred if the corresponding specified values are exceeded or undershot.

A location determination according to claim 8 additionally allows a determination of a defect location by way of the measured variable determination.

The determination of an actual measured variable according to claim 9 has the advantages already explained hereinabove.

The determination of a target measured variable according to claim 10 can be implemented for reference or calibration purposes.

A difference determination according to claim 11 is implemented independently of a target structure-dependent substrate, with the result that in fact only defect-dependent measured variables are determinable.

The advantages of a computer program product according to claim 12 correspond to those which have already been explained hereinabove with reference to the defect analysis method.

A corresponding statement applies to the advantages of a metrology system according to claim 13. Measurement light of the metrology system may have a wavelength in the EUV range, in particular in the range between 5 nm and 30 nm, for example at 13.5 nm. Alternatively, the metrology system can also operate using measurement light in the DUV range, for example measurement light at a wavelength of 193 nm or 248 nm.

Component parts of the metrology system may comprise a light source for illumination and imaging light, an illumination optical unit for illuminating an object field, an imaging optical unit for imaging the object field into an image field and a spatially resolving detection device for detecting an illumination intensity distribution within the image field. The metrology system may also include an open-loop/closed-loop control device, by means of which a course of the test path, a distribution of test path locations along the test path and, within the object field, a defined or predetermined field portion to be measured can be specified.

The metrology system can be used to measure a lithography mask provided for projection exposure for producing semiconductor components with very high structure resolution, which is better than 500 nm, for example, or better than 100 nm and which can be better than 30 nm and better than 10 nm, in particular.

### BRIEF DESCRIPTION OF DRAWINGS

An exemplary embodiment of the invention is explained in greater detail below with reference to the drawing, in which:

FIG. 1 schematically shows a metrology system for carrying out a defect analysis with the aid of determining, as a result of illumination and imaging under illumination and imaging conditions corresponding to those of an optical production system, a production aerial image of an object to be measured, with a plan view of an object field and a plan view of a measurement field in a current z-position additionally being shown;

FIG. 2 shows a magnified plan view of a line structure of the object to be measured in the form of a structured component, with an additional illustration of four locations along a test path at which a local deviation between an actual structure dimension and a target structure dimension of the component is tested, the test being carried out along a coordinate of deviation extending across the test path;

FIG. 3 shows, once again in a plan view, another example of a structure of a structured component with structures in the form of contact holes, which structure is to be tested and subjected to a defect analysis, with local deviations between an actual structure dimension and a target structure dimension of the illumination element once again being illustrated and with a closed test path running along a circumference of a contact hole in this case;

FIG. 4 shows, once again in a plan view, another example of a structure of a structured component with structures in the form of a rounded corner structure, which structure is to be tested and subjected to a defect analysis, with a deviation of an actual structure dimension from a target structure dimension once again being illustrated and with a curvilinear test path running along a rounded corner line of the target structure; and

FIG. 5 schematically shows a plan view of the object field with a variant of a structural portion of the object to be measured.

### DETAILED DESCRIPTION

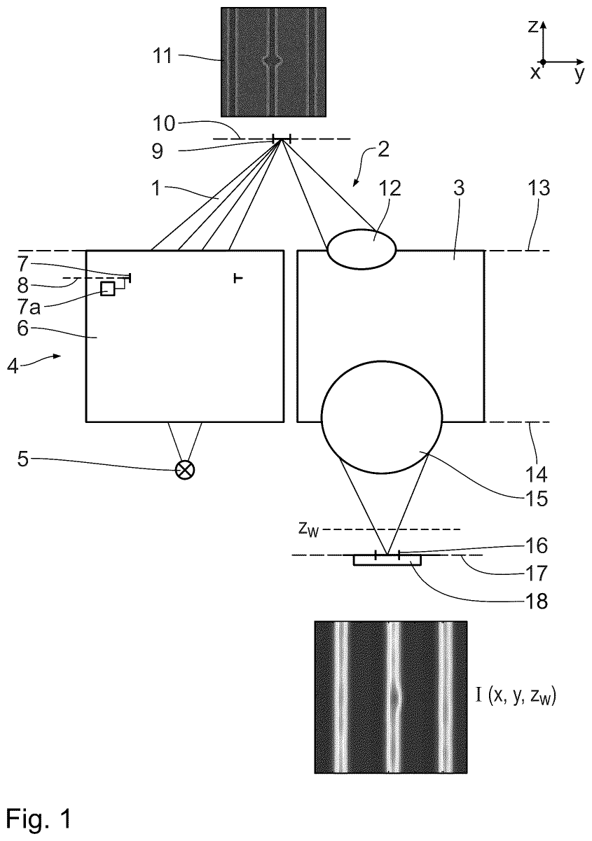

FIG. 1 shows, in a plane corresponding to a meridional section, a beam path of

EUV illumination light or EUV imaging light 1 in a metrology system 2 comprising an imaging optical unit 3, which is schematically reproduced by a box in FIG. 1. The illumination light 1 is generated in an illumination system 4 of the projection exposure apparatus 2.

The metrology system 2 is described hereinafter using the example of a EUV metrology system. Depending on the requirements placed on metrology, the metrology system can also be used as a DUV metrology system with a measurement light wavelength of 193 nm or 248 nm, for example.

In order to facilitate the representation of positional relationships, a Cartesian xyz-coordinate system will be used hereinafter. The x-axis in FIG. 1 runs perpendicularly to the plane of the drawing and out of the latter. The y-axis in FIG. 1 runs towards the right. The z-axis in FIG. 1 runs upwards.

The illumination system 4 contains an EUV or DUV light source 5 and an illumination optical unit 6, depicted schematically in each case. The light source can be a laser plasma source (LPP; laser produced plasma) or a discharge source (DPP; discharge produced plasma). In principle, a synchrotron-based light source can also be used, for example a free electron laser (FEL). A used wavelength of the illumination light 1 can lie in the range of between 5 nm and 30 nm. In principle, in the case of a variant of the metrology system 2, it is also possible to use a light source for another used light wavelength, for example for a used wavelength of 193 nm or 248 nm.

The illumination light 1 is conditioned in the illumination optical unit 6 of the illumination system 4 such that a specific illumination setting of the illumination, which is to say a specific illumination angle distribution, is provided. Said illumination setting corresponds to a specific intensity distribution of the illumination light 1 in an illumination pupil of the illumination optical unit of the illumination system 4. A pupil stop 7 arranged in a pupil plane 8 of the illumination optical unit 6 serves to provide the respective illumination setting.

The pupil stop 7 is held in a stop holder 7a. This may be a quick-change stop holder which enables a replacement of the pupil stop 7 currently used in the illumination with at least one change pupil stop. Such a quick-change holder may comprise a cartridge having a plurality of pupil stops 7, in particular different pupil stops, for specifying various illumination settings.

An image-side numerical aperture of the imaging optical unit 3 is 0.7. Depending on the embodiment of the imaging optical unit 3, the image-side numerical aperture is greater than 0.5 and may also be 0.55, 0.6, 0.65, 0.75, 0.8 or even greater. This image-side numerical aperture of the imaging optical unit 3 is adapted to the image-side numerical aperture of the production projection exposure apparatus to be simulated by the imaging by the metrology system. Accordingly, the illumination setting set by the dipole pupil stop 7 is also adapted to a production illumination setting of this production projection exposure apparatus.

The metrology system 2 is used as follows: Initially, the imaging optical unit 3 on the one hand and—by way of the respective pupil stop 7 on the other hand—an image-side numerical aperture, and an illumination setting are set, the latter corresponding to the best possible extent to the illumination and imaging conditions of a production projection exposure apparatus to be measured.

With the illumination setting that is respectively set, the illumination light 1 illuminates an object field 9 of an object plane 10 of the metrology system 2. Thus, a lithography mask 11, which is also referred to as a reticle, is arranged in the object plane 10 as an object to be illuminated during the production as well. The lithography mask 11 represents the object in the form of a structured component which should be measured using the metrology system 2. The metrology system 2 is used to carry out a defect analysis of the lithography mask 11. The defect analysis is implemented with the aid of aerial image measurement by the metrology system 2.

A structural portion of the lithography mask 11 is shown schematically above the object plane 10, which extends parallel to the xy-plane, in FIG. 1. Said structural portion is depicted such that it lies in the plane of the drawing in FIG. 1. The actual arrangement of the lithography mask 11 is perpendicular to the plane of the drawing of FIG. 1 in the object plane 10.

The illumination light 1 is reflected from the lithography mask 11, as depicted schematically in FIG. 1, and enters an entrance pupil 12 of the imaging optical unit 3 in an entrance pupil plane 13. The utilized entrance pupil 12 of the imaging optical unit 3 is round or, as schematically indicated in FIG. 1, has an elliptic edge.

Within the imaging optical unit 3, the illumination or imaging light 1 propagates between the entrance pupil plane 13 and an exit pupil plane 14. A circular exit pupil 15 of the imaging optical unit 3 lies in the exit pupil plane 14. The imaging optical unit 3 can be anamorphic and generates the circular exit pupil 15 from the round or elliptic entrance pupil 12.

The imaging optical unit 3 images the object field 9 into a measurement or image field 16 in an image plane 17 of the projection exposure apparatus 2. Below the image plane 17, FIG. 1 schematically shows an imaging light intensity distribution I which is measured in a plane spaced apart from the image plane 17 by a value z_{W} in the z-direction, which is to say an imaging light intensity at a defocus value z_{W}.

The imaging light intensities I(x, y, Z_{w}) at the various z-values around the image plane 17 are also referred to as a 3D aerial image of the projection exposure apparatus 2.

A spatially resolving detection device 18, which can be a CCD camera or a CMOS camera, is arranged in the image plane 17, which represents a measurement plane of the metrology system 2. The detection device 18 registers the imaging light intensities I(x, y, z_{W}).

The imaging optical unit 3 may have a magnifying imaging scale greater than 100 when imaging the object field 9 into the image field 16. This imaging scale can be greater than 200, can be greater than 250, can be greater than 300, can be greater than 400, and can be greater than 500. The imaging scale of the imaging optical unit 3 is regularly less than 2000.

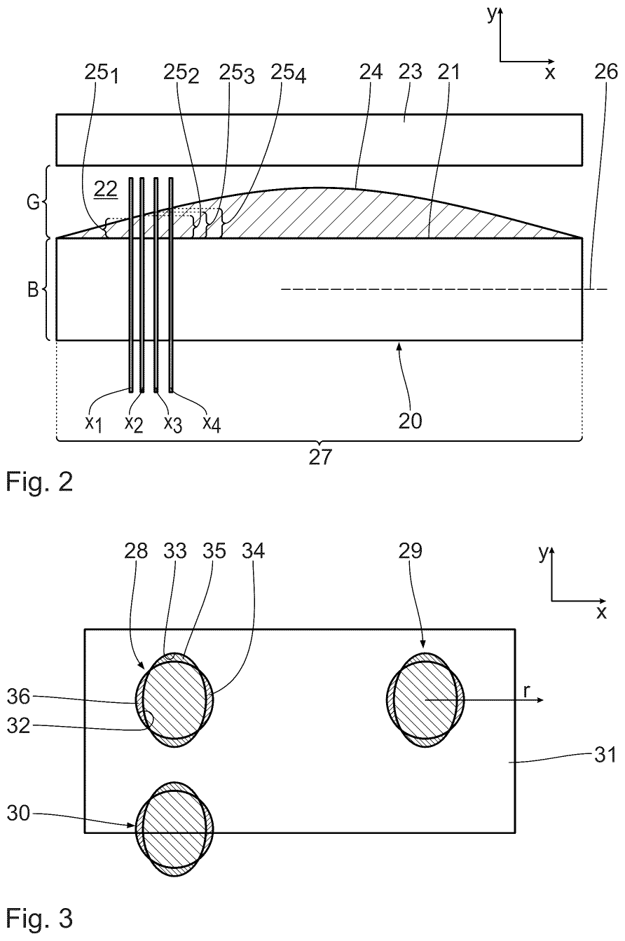

FIG. 2 schematically shows an enlarged plan view of a variant of a structure 20 of the lithography mask 11, which is subjected to a defect analysis by use of the metrology system 2. The structure 20 is a horizontal structure which runs along an x-direction of the coordinate system of FIG. 2. Alternatively, the structure 20 can also be a vertical structure running along the y-direction or a line structure running along another direction in the object plane 10.

In FIG. 2, a target structure dimension 21 of the structure 20 is reproduced in rectangular fashion with a structure width B. The structure width B can be in the range between 20 nm and 200 nm. The structure 20 may be a positive structure which is raised above adjacent structural regions, or a structure made of a certain first material of the lithography mask 11.

The structure 20 adjoins an adjacent structure 23 by way of a gap structure 22, which likewise runs along the x-direction and has gap width G. The gap structure 22 may be designed as a negative structure which is depressed in comparison with the positive structure 20 or as a structure made of a different material to that of the structure 20. The gap width G of the gap structure 22 can be in the range between 20 nm and 200 nm and, for example, in the range between 60 nm and 100 nm.

An actual structure dimension 24 of the horizontal structure 20 in the boundary region between the horizontal structure 20 and the gap structure 22 is depicted with exaggerated magnification in FIG. 2.

The actual structure dimension 24 is illustrated by way of example in FIG. 2 as an excess defect structure protruding from the target structure dimension 21 into the gap region of the gap structure 22.

A local deviation 25 between the actual structure dimension 24 and the target structure dimension 21 of the component 11 can be checked with the aid of the metrology system 2. This deviation 25ᵢ is checked at a location xᵢ of a test path 26. The test path 26 is rectilinear and extends along the coordinate x, which is horizontal in FIG. 2. The local deviation 25ᵢ is measured and tested along the y-coordinate, which is to say along a deviation coordinate y which extends across the test path 26 and specifically perpendicular thereto. The deviation coordinate y extends perpendicular to test path 26 at the respective test path location xᵢ. These test path locations xᵢ are also referred to as slices.

FIG. 2 shows a total of four different test path locations x₁, x₂, x₃ and x₄, at which the respective local deviation 25₁ to 25₄ is measured in exemplary fashion. Overall within the scope of the defect analysis, this local deviation 25ᵢ is measured and tested at a multiplicity of test path locations xᵢ along the x-coordinate of the component 11 and along an entire test region 27 in particular.

The test path 26 can be scanned when repeating the test for the plurality of different test path locations xᵢ.

This measurement and test of the local deviation 25ᵢ along the entire test region 27 at a plurality of local test locations xᵢ is followed during the defect analysis by the determination of a summed deviation Σᵢ₌₁^{N}25ᵢ between the actual structure dimension 24 and the target structure dimension 21.

The summation can be performed as an integration in a software implementation of the defect analysis method.

During the defect analysis, the measured and tested local deviation 25ᵢ is compared with a local deviation tolerance value 25_{T}.

Further, in defect analysis, the summed deviation corresponding to the entire area in which the actual structure dimension 24 deviates from the target structure dimension 21 over the test region 27 is compared with a summation deviation tolerance value 25_{S}.

A check is carried out on the basis of these two comparison steps with the tolerance values 25_{T}, 25_{S} as to whether the actual structure dimension 24 is, overall, a tolerable structure dimension for the lithography mask 11.

When determining the summed deviation, there can be a separate summation of, firstly, a positive deviation, in which the actual structure dimension 24 is greater than the target structure dimension 21 at the respective test location xᵢ, and of, secondly, a negative deviation, in which at the respective test location xᵢ the actual structure dimension 24 is smaller than the target structure dimension, the actual structure dimension 24 thus deviating from the target structure dimension 21 away from the gap structure 22, increasing the gap width G.

FIG. 3 shows a further variant of structures which can be examined by the metrology system 2 with the aid of the defect analysis, using the example of contact holes 28, 29, 30 in a variant of lithography mask 11. FIG. 3 also illustrates a region of interest (ROI) 31 which coincides with the object field 9 of the metrology system 2. This ROI 31 contains all of the two contact holes 28 and 29 and half of the contact hole 30.

FIG. 3 in each case illustrates a target structure dimension 32, circular in each case in the illustrated variant according to FIG. 3, of the respective contact hole 28 to 30. Moreover, a respective actual structure dimension 33 of the respective contact hole 28 to 30 is shown in FIG. 3, which in the illustrated embodiment is designed in each case as an elliptically deformed contact hole with a longer half-axis in the y-direction. The deviations between the actual structure dimension 33 and the target structure dimension 32 are once again very exaggerated in FIG. 3.

In an EUV metrology system application, the contact holes 28 to 30 have a typical diameter of the order of 80 nm. In a DUV metrology system application, the contact holes 28 to 30 have a typical diameter ranging between 180 nm and 400 nm.

On account of the deviation between the round target structure dimensions 32 and the elliptical actual structure dimensions 33, two regions 35 which are referred to as intrusion regions arise along a test path 34 around the circumference of the respective target structure dimension 32, in which regions a distance between an edge of the actual structure dimension 33 and a center of the target structure dimension 32 is greater than a radius of the target structure dimension 32. These two intrusion regions 35 are spaced from the center of the respective target structure dimension 32 in both +y- and −y-directions.

Furthermore, on account of the elliptical actual structure dimension 33 deviating from the round target structure dimension 32, two extrusion regions 36 arise in which the radius of the target structure dimension 32 is greater than a distance between the edge of the actual structure dimension 33 and the center of the target structure dimension 32. These two extrusion regions 36 are spaced from the center of the respective target structure dimension 32 in both +x- and −-x-directions.

Within the scope of the defect analysis of the contact holes 28 to 30, the local deviation between the actual structure dimension 33 and the target structure dimension 32 is measured and checked at a respective circumferential location of the test path 34 and along a radial deviation coordinate, which correspondingly extends across the test path 34, with the aid of the metrology system 2. This is repeated for a plurality of circumferential test path locations within the entire circumference of test path 34 around the respective contact holes 28 to 30. In the case of contact hole 30, the test path 34 is designed as a semicircle within the ROI 31.

The test path 34 is curved, specifically circular or partly circular. The test path 34 runs along a closed curve at the contact holes 28 and 29. The radial deviation coordinate extends perpendicular to test path 34 at the respective test path location.

In accordance with what has already been discussed above in the context of FIG. 2, a summed deviation (Σᵢ₌₁^{N}25ᵢ) between the actual structure dimension 33 and the target structure dimension 32 is then determined in turn over the entire circumferential region of the test path 34, which is to say over the test region. Then, once again, the local deviation is compared with a local deviation tolerance value 25_{T} and the summed deviation (Σᵢ₌₁^{N}25ᵢ) is compared with a summation deviation tolerance value 25_{S}

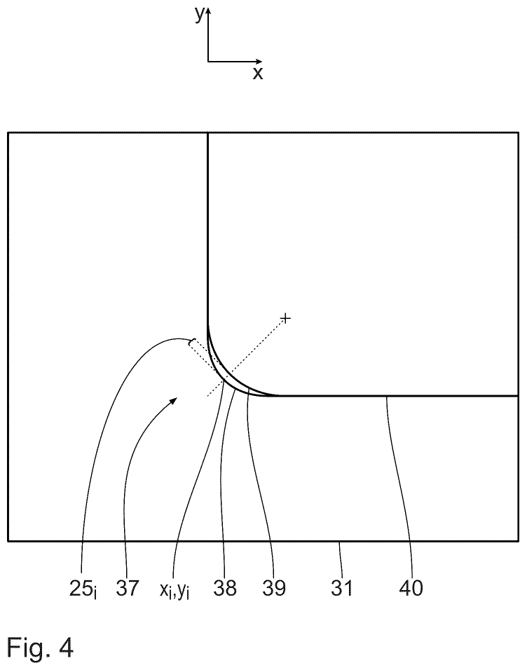

FIG. 4 shows an example of a structure of the lithography mask 11, which is subjected to the defect analysis, wherein the structure is designed as a corner structure with a target structure dimension 38 embodied as a spherical corner and an actual structure dimension 39 which is more set back in comparison therewith in the example shown in FIG. 4. The corner structure 37 encloses, for example, a positive structure region or a region made of a first material of the lithography mask 11 and adjoins, for example, a further region which is embodied as a negative structure region or as a region made of another material and which is designed to complement the corner structure 37.

Within the scope of the defect analysis of the corner structure 37, a test path 40 runs along an edge region of the target structure dimension 38 of the corner structure 37. Overall, the test path 40 runs in curved fashion with an overall angle of curvature of 90° over the corner region 37.

Within the scope of the defect analysis of corner structure 37, a local deviation between the actual structure dimension 39 and the target structure dimension 38 is once again measured and checked. Once again, this deviation is measured and checked perpendicular to the respective test path location on test path 40. Thus, where the test path 40 runs along the x-coordinate, the deviation coordinate runs in the y-direction. Where the test path 40 runs along the y-coordinate, the deviation coordinate runs in the x-direction. In the spherical transition region between the horizontal and the vertical course of the test path 40, the deviation coordinate runs perpendicular to a tangent on the test path 40, which is to say radially to the center of the associated sphere in the event of the target structure dimension 38 being spherical in the region of the corner structure 37.

This local deviation 25ᵢ is illustrated in FIG. 4 for a test location xᵢ, yᵢ along the test path 40.

Along the test path 40, the test is repeated for a plurality of different test path locations xᵢ, yᵢ along the respective deviation coordinate within a test region of the test path 40, which is to say within the entire corner region 37 shown within the ROI 31 in FIG. 4. The summed deviation (Σᵢ₌₁^{N}25ᵢ) between the actual structure dimension 39 and the target structure dimension 38 is then determined over the entire test region of test path 40. Subsequently, once again, the local deviation is compared with the local deviation tolerance value 25_{T} and the summed deviation (Σᵢ₌₁^{N}25ᵢ) is compared with the summation deviation tolerance value 25_{S}.

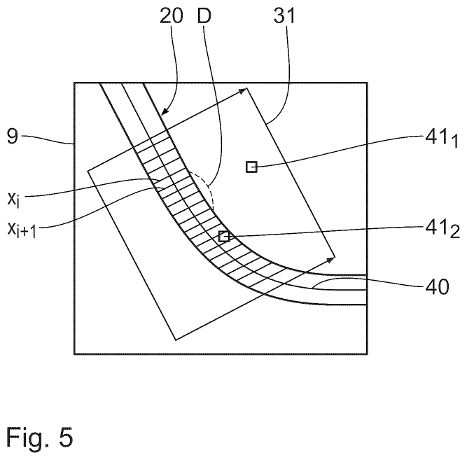

FIG. 5 shows a variant of the structure 20 of the object to be measured, which is to say the lithography mask 11, within the object field 9 of the metrology system 2. The structure 20 is illustrated as a curvilinear structure which has a structure width B, once again in the range between 20 nm and 200 nm, for example, and is embodied in a raised manner relative to adjacent object portions.

Components and functions corresponding to those which have already been explained hereinabove with reference to FIGS. 1 to 4 have the same reference signs and will not be discussed in detail again.

FIG. 5 also illustrates the region of interest (ROI) 31, which represents a defined field portion within the object field 9 of the metrology system 2. Furthermore, FIG. 5 illustrates the course of the test path 40, which is also curved in this case, and a course of the test path locations xᵢ running across this test path 40 in each case.

Two test path locations xᵢ, xᵢ₊₁, which are scanned during the defect analysis and checked for a local deviation, are highlighted as an example, as already explained hereinabove.

An additional measured variable is additionally determined in the ROI 31 by use of the spatially resolving detection device 18 within the scope of the defect analysis, independently of the arrangement of the test path locations xᵢ. This is at least one of the following measured variables:

A maximum intensity of illumination light 1 in the ROI 31, which is to say the maximum intensity measured in the image field 16 at the image location of the ROI 31;

A minimum intensity of illumination light 1 in the ROI 31, which is to say the minimum intensity measured in the image field 16 at the image location of the ROI 31; and/or

A mean intensity of the illumination light 3, averaged over the ROI 31, which is to say averaged over the image of the ROI 31 in the image field 16, and measured by use of the spatially resolving illumination device 18.

FIG. 5 elucidates, by way of example, two possible locations 411, 412 of an occurrence of the maximum intensity of the illumination light 1 in the ROI 31, detected by way of the detection device 18, or the minimum intensity of the illumination light 3 in the ROI 31, in turn detected by way of the detection device 18. Location 41; is outside the structure 20 of object 11. Location 412 is within the structure 20 of the object field.

The structure 20 can be a structure with a defect or else a structure without a defect, which is to say a defect-free structure. A defect D, which is to say a deviation between an actual structure dimension 24 and a target structure dimension 21 (cf. the description in relation to FIG. 2), is indicated by dashes as a bulge of an edge contour of the structure 20 in FIG. 5.

Insofar as the defect is not present, the image representation of ROI 31 by way of detection device 18 is a reference image. Should the defect D be present, the image representation is a defect image. The scope of the defect analysis may also include the determination of a difference image between the reference image and the defect image.

The respective measured variable of “maximum intensity,” “minimum intensity” and/or “mean intensity” can be determined in the defect image, in the reference image or else in the difference image.

Further measurement information about the ROI 31 can be obtained by way of this independent measured variable determination, in addition to the local defect analysis which was explained above mainly in connection with FIGS. 2 to 4. This measurement information can be used, for example, to carry out a comparison of the specific intensity measured variables with specified target maximum and target minimum intensity values. A decision regarding the presence of a defect within ROI 31 can be made independently of the test path scanning in this way.

A software algorithm for carrying out the defect analysis can be designed as a computer program and be part of a computer program product which is stored on a computer-suitable medium and comprises computer-readable program means, which cause a computer to carry out the various steps of the defect analysis.

In some implementations, after the defect analysis is performed, the computer generates a defect analysis report showing the results of the defect analysis. The defect analysis report can include information about, e.g., the locations of the defects and the types of the defects. A defect repair tool can be used to repair the defects shown in the defect analysis report. There are a number of ways to repair a defect, such as depositing material to a structure, use etching to remove material from a structure, or applying energy (e.g., using a light beam or a particle beam) to locally modify one or more properties (e.g., density and/or refractive index) of a substrate. The repair process physically modifies the object 11 (e.g., the lithography mask) to repair the defects based on information provided in the defect analysis report. After the repair process is performed, the defect analysis can be performed again to determine whether all of the defects have been corrected. If the defects are not completely corrected, the repair process can be performed again to correct the remaining defects, and so forth.

In the example of FIG. 1, the imaging optical unit 3 can include, in additional to the components already described above, one or more lenses, one or more reflecting surfaces, such as mirrors, and/or one or more optical filters. The illumination optical unit 6 can include, in additional to the components already described above, one or more lenses, one or more reflecting surfaces, such as mirrors, and/or one or more optical filters. The spatially resolving detection device 18 can be, e.g., a charge coupled device (CCD) sensor or a complementary metal-oxide semiconductor (CMOS) sensor. A defect repair tool can include, e.g., a source for generate an energy beam, such as a laser beam or a particle beam, which can be an electron beam or an ion beam. The defect repair tool can include a beam steering mechanism to steer the energy beam towards the location of the defect. The defect repair tool can include one or more storage containers for storing one or more precursor gases that interact with the energy beam to form a deposit material that can be deposited on the object 11 or form an etchant that can etch material from the object 11. The energy beam can also be directed to the substrate of the object 11 to generate pixels in which one or more physically properties of the substrate are locally modified.

The computer used to carry out the defect analysis and other data processing described above can be implemented using one or more computing devices that include one or more one or more data processors configured to execute one or more programs that include a plurality of instructions according to the principles described above.

The one or more computing devices can include one or more data processors for processing data, one or more storage devices for storing data, and/or one or more computer programs including instructions that when executed by the one or more computers cause the one or more computers to carry out the processes. The one or more computing devices can include one or more input devices, such as a keyboard, a mouse, a touchpad, and/or a voice command input module, and one or more output devices, such as a display, and/or an audio speaker. In some implementations, the one or more computing devices can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computing devices can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, flash storage devices, and solid state drives; magnetic disks, e.g., internal hard disks or removable disks; magneto-optical disks; and CD-ROM, DVD-ROM, and/or Blu-ray discs.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium, such as CD-ROM, DVD-ROM, Blu-ray disc, a solid state drive, or a hard drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

Although the present invention has been described with reference to exemplary embodiments, it is modifiable in various ways. The following examples are also disclosed:

Example 1: A method comprising:

analyzing defects of a structured component, including:
testing a local deviation between an actual structure dimension (of the component and a target structure dimension of the component, with the local deviation being checked at a location of a test path along a deviation coordinate which extends across the test path;
repeating the test at a plurality of different test path locations within a test region of the test path;
determining a summed local deviation between the actual structure dimension and the target structure dimension over the test region;
comparing the local deviation with a local deviation tolerance value;
comparing the summed local deviation with a summation deviation tolerance value; and
determining the defects of the structured component based on a first result of the comparison of the local deviation with the local deviation tolerance value and a second result of the comparison of the summed local deviation with the summation deviation tolerance value; and

physically modifying the structured component based on a result of the analysis of the defects of the structured component to repair the defects.

Example 2: The method of example I wherein physically modifying the structured component comprises at least one of depositing a material on the structured component, etching material away from a portion of the structured component, or applying energy to locally modify one or more physical characteristics of the structured component.

Example 3: The method of example 1 wherein the test path runs in a straight line along a test coordinate.

Example 4: The method of example 1 wherein the test path is curved.

Example 5: The method of example 1 wherein the deviation coordinate extends at right angles to the test path at the respective test path location.

Example 6: The method of example 1 wherein a positive deviation and a negative deviation are summed separately.

Example 7: The method of example 1 wherein in a defined field portion within an object field of an imaging optical unit of a metrology system used to carry out the method, a spatially resolving detection device of the metrology system, arranged in an image field of the imaging optical unit, is used to determine at least one of the following measured variables:

a maximum intensity of illumination and imaging light of a light source of the metrology system in the defined field portion,

a minimum intensity of illumination and imaging light of a light source of the metrology system in the defined field portion, or

a mean intensity of illumination and imaging light of a light source of the metrology system, averaged over the defined field portion.

What is claimed is:

1. A method for analyzing defects of a structured component, including the following steps:
testing a local deviation between an actual structure dimension (of the component and a target structure dimension of the component, with the local deviation being checked at a location of a test path along a deviation coordinate which extends across the test path,
repeating the test at a plurality of different test path locations within a test region of the test path,
determining a summed local deviation between the actual structure dimension and the target structure dimension over the test region,
comparing the local deviation with a local deviation tolerance value, and
comparing the summed local deviation with a summation deviation tolerance value.

2. The method of claim 1, wherein the test path runs in a straight line along a test coordinate.

3. The method of claim 1, wherein the test path is curved.

4. The method of claim 3, wherein the test path runs along a closed curve.

5. The method of claim 1, wherein the deviation coordinate extends at right angles to the test path at the respective test path location.

6. The method of claim 1, wherein a positive deviation and a negative deviation are summed separately.

7. The method of claim 1, wherein in a defined field portion within an object field of an imaging optical unit of a metrology system used to carry out the method, a spatially resolving detection device of the metrology system, arranged in an image field of the imaging optical unit, is used to determine at least one of the following measured variables:
a maximum intensity of illumination and imaging light of a light source of the metrology system in the defined field portion and/or
a minimum intensity of illumination and imaging light of a light source of the metrology system in the defined field portion and/or
a mean intensity of illumination and imaging light of a light source of the metrology system, averaged over the defined field portion.

8. The method of claim 7, wherein a location of the occurrence of the maximum intensity and/or the minimum intensity within the defined field portion is determined.

9. The method of claim 7, wherein the measured variable is determined as the actual measured variable on the basis of an image of a structure of the component with a defect in the defined field portion.

10. The method of claim 7, wherein the measured variable is determined as the target measured variable on the basis of an image of a structure of the component without a defect in the defined field portion.

11. The method of claim 9, wherein the measured variable is determined as the difference between the actual measured variable and the target measured variable.

12. A computer program product stored on a computer-compatible medium and comprising the following: computer-readable program means which cause a computer to carry out the various steps of the defect analysis of claim 1.

13. A metrology system for carrying out the method of claim 1.

14. The computer program product of claim 12, wherein the test path runs in a straight line along a test coordinate.

15. The computer program product of claim 12, wherein the test path is curved.

16. The computer program product of claim 12, wherein the deviation coordinate extends at right angles to the test path at the respective test path location.

17. The metrology system of claim 13, wherein the test path runs in a straight line along a test coordinate.

18. The metrology system of claim 13, wherein the test path is curved.

19. The metrology system of claim 13, wherein the deviation coordinate extends at right angles to the test path at the respective test path location.

20. The metrology system of claim 13, wherein a positive deviation and a negative deviation are summed separately.
